(19) United States
(12) Patent Application Publication
(10) Pub. No.: US 2002/0075020 A1
(43) Pub. Date: Jun. 20, 2002

(54) Test cell structure for estimating electrical characteristics of closely-spaced bond pads formed on a substrate

(76) Inventors: Mathias Boettcher, Dresden (DE); Thomas Werner, Dresden (DE)

Correspondence Address: J. Mike Amerson, Williams Morgan & Amerson, P.C., Suite 250, 7676 Hillmont, Houston, TX, 77040, US

(21) Appl. No.: 10/007,760

(22) Filed: Nov. 8, 2001

(30) Foreign Application Priority Data
Dec. 15, 2000 (DE) 100 62 661.0

(51) Int. Cl. G01R 31/02

(52) U.S. Cl. 324/754

(57) ABSTRACT

A test cell structure is provided that allows a precise measurement of electrical characteristics, such as the electrical resistance, between adjacent bond bumps in relation to a decreasing pitch between the bumps. The test cell structure comprises a substrate with an at least partially insulating surface, central and peripheral bond bumps formed on the partially insulating surface, and an insulating layer provided between the bond bumps. At last two respective distances of central bond bumps and associated peripheral bond bumps are different so that a variation of the electrical resistance with respect to variation of the distance of adjacent bond bumps can be determined. Particularly, when the distances are selected to be 80 μm and less, it is possible to relate the measurements obtained to corresponding design rules for semiconductor devices. Moreover, a test cell receiving structure is disclosed that preferably matches the design of a test cell structure so that electrical characteristics can be obtained either for the test cell structure alone or a combined device in which a test cell structure is flip chip bonded to the test cell receiving structure. Furthermore, a method of determining electrical characteristics of adjacent bond bumps is disclosed.

### BACKGROUND OF THE INVENTION

1. Field of the Invention

The present invention relates to the field of manufacturing of semiconductor devices, and particularly to packaging of integrated circuits and an apparatus and a method of monitoring electrical characteristics of closely-spaced bond pads formed on a substrate to obtain information on a corresponding bond structure in an integrated circuit.

2. Description of the Related Art

In the manufacturing process of integrated circuits (ICs), a large number of individual semiconductor elements, such as insulated gate field-effect transistors or metal-oxide semiconductor field-effect transistors (MOSFETs), are formed within a small chip area. These individual semiconductor elements are internally connected to establish an electronic circuit of high functionality and complexity, such as memory devices, logic devices and microprocessor devices. Particularly, logic devices and microprocessors require a large number of input/output terminals to provide for communication to peripheral electronic devices. Due to the steadily decreasing feature sizes of modem integrated circuits, the number of semiconductor elements per chip is rapidly increasing, allowing the design of circuits with increased functionality. Accordingly, the number of input/output terminals per chip is also increasing which, in turn, reduces the available space and, hence, the pitch of respective bond pads that are formed on the semiconductor chip for providing electrical contact to the package confining the semiconductor chip. Providing outside contacts to peripheral devices and packaging of the semiconductor chip is not performed on a wafer basis as is the manufacturing process of the semiconductor chip, and is therefore an extremely cost-intensive procedural step. Furthermore, reliability and functionality of the semiconductor chip strongly depend on the characteristics of the electrical contacts and the type of packaging, since not only electrical contact to outside sources has to be provided, but especially the package also has to insure the integrity of the semiconductor chip with respect to mechanical and environmental influences. Moreover, heat created during the operation of the semiconductor chip has to be transported to the outer surface of the semiconductor package so as to maintain the temperature in the semiconductor chip within a specified range.

In order to more efficiently integrate one or more semiconductor chips into an appropriate package, usually so-called flip chip bonding is performed which eliminates the necessity of contacting the semiconductor chip with single wires. In flip chip technology, an array of contact portions, so-called bond bumps, is formed on corresponding contact pads provided on an insulating layer of the semiconductor chip. The conductive bond bumps, such as small solder balls, protrude from the surface of the semiconductor chip, depending on the diameter of the solder balls. Thereafter, the semiconductor chip is inverted or flipped and placed on a wiring substrate having contact pads formed thereon so that the bond bumps are aligned with the contact pads on the wiring substrate. Next, the solder of the bumps is re-flowed to electrically and physically connect the semiconductor chip to the wiring substrate. Particularly when a plurality of semiconductor chips is provided on a common substrate, the flip chip technology is advantageous since no wire leads are required to connect the chips to the substrate so that the chips may be placed very close together. Accordingly, circuit density, and thus signal performance, is maximized since the interconnection delay, i.e., the signal delay, between different chips is maintained at a low rate.

Since the feature density in individual semiconductor chips is also steadily decreasing, the space or the pitch between adjacent bond bumps also decreases due to the increased number of required inputs and outputs for the device, particularly in the case of microprocessors and complex logic circuits. Reducing the pitch of adjacent bond bumps, however, may give rise to a plurality of problems such as reduced electrical resistance between adjacent bond bumps or even shorts which may result in a degraded performance or even in a total loss of functionality of the corresponding semiconductor chip. Moreover, since the semiconductor chip is subjected to considerable thermal stress due to the different materials used in manufacturing the semiconductor chip and due to the considerable thermal gradient between the interior and the exterior of the semiconductor chip during operation, electrical properties such as resistance, capacitance and inductance may vary during operation and over time, thereby considerably reducing reliability of the device.

Since establishment of and adherence to good chip design rules is essential in achieving high yields, corresponding rules regarding the particular package type used must be compatible with the assembly equipment, and with the corresponding process flow for forming, for example, the final semiconductor layers carrying the bond bumps. Arranging the bond bumps more densely, and therefore, reducing the pitch between adjacent bond bumps, is thus a critical manufacturing step as well as a critical design step for future chip generations.

In view of the above-mentioned problems, a need exists for determining electrical characteristics of flip chip bonded structures with respect to decreasing distances of adjacent bond bumps. The present invention solves, or at least reduces, some or all of the aforementioned problems.

### SUMMARY OF THE INVENTION

In view of the above problems, according to one aspect of the present invention, a test cell structure for determining electrical characteristics between adjacent bond bumps is provided, wherein the test cell structure comprises a substrate having an at least partially insulating surface, a first central bond bump formed on the at least partially insulating surface, and a second central bond bump formed on the at least partially insulating surface. The test cell structure further comprises a first peripheral bond bump formed on the at least partially insulating surface and spaced apart from the first central bond bump by a first distance, and a second peripheral bond bump formed on the at least partially insulating surface and spaced apart from the second central bond bump by a second distance, wherein the second distance is less than the first distance. The test cell structure also comprises an insulating layer at least partially formed between the central bond bump and the first and second peripheral bond bumps, a first central contact pad for providing electrical contact to an external device, the first central contact pad being connected to the first central bond bump by a first central contact line, and a second central contact pad for providing electrical contacts to an external device, the second central contact pad being connected to the second central bond bump by a second central contact line, and a peripheral contact pad for providing electrical contact to an external device, the peripheral contact pad being connected to the first and second peripheral bond bumps by a peripheral contact line, wherein an electrical property of the first and second central bond bumps and the first and second peripheral bond bumps with respect to the first and second distances are measurable via the first and second central contact pads and the peripheral contact pad.

According to this aspect of the present invention, the test cell structure provides for a first and second central bond bump that have, respectively, a first and a second distance to corresponding peripheral bond bumps. Since the peripheral bond bumps are connected to a single contact pad, a measurement device can easily be connected to the first central bond bump and the peripheral bond bumps and/or to the second central bond bump and the peripheral bond bumps. Since the second distance is less than the first distance, an electrical property, such as the electrical resistance, between adjacent bond bumps for at least two different distances can be measured and can be related to a corresponding semiconductor chip structure so as to estimate the influence of pitch reduction on, for example, the probability of causing a short. The test cell structure is well-suited for predicting the characteristics of correspondingly manufactured semiconductor devices. To this end, the test cell structure is preferably produced according to a process being similar or identical to a corresponding process flow that is or might be used in semiconductor manufacturing. Moreover, the test cell structure according to the present invention may easily be enlarged to include a plurality of central bond bumps and peripheral bond bumps, such that a plurality of different distances may be measured within the same measurement cycle and related to corresponding present or future semiconductor device structures. In this manner, the dependency of electrical properties such as electrical resistance, capacitance and inductance, of adjacent bond bumps may be precisely investigated to reliably predict the characteristics of bond structures when the pitch of bond bumps decreases.

According to another aspect of the present invention, the test cell receiving structure for receiving a test cell structure by flip chip bonding is provided, the test cell receiving structure comprises a wiring substrate, a first central bond pad formed on the wiring substrate for bonding thereon a bond bump, and a second central bond pad formed on the wiring substrate for bonding thereon a bond bump. The test cell receiving structure further comprises a first peripheral bond pad for bonding thereon a bond bump, the first peripheral bond pad formed on the wiring substrate and spaced apart from the first central bond pad by a first distance, and a second peripheral bond pad for bonding thereon a bond bump, wherein the second peripheral bond pad is formed on the wiring substrate and spaced apart from the second central bond pad by a second distance, the second distance being less than the first distance.

Similarly to the first aspect, the test cell receiving structure provides a convenient means for investigating electrical characteristics of bond structures that are primarily used in semiconductor manufacturing. The test cell receiving structure is particularly advantageous in combination with the test cell structure described above since both devices may be electrically and physically connected by flip chip bonding so that the electrical characteristics of the resulting structure can easily be investigated with respect to decreasing distances between adjacent contact portions. Preferably, the test cell receiving structure is manufactured in accordance with present or future design rules for a corresponding semiconductor device.

According to still another aspect of the present invention, a test cell structure for determining electrical characteristics between adjacent bond bumps is provided. The test cell structure comprises a substrate having an at least partially insulating surface, a plurality of central bond bumps formed on the at least partially insulating surface, each central bond bump having two or more adjacent peripheral bond bumps spaced apart therefrom by a substantially equal distance. In the test cell structure, at least two of the central bond bumps have distances to their corresponding peripheral bond bump that are different from each other.

Since this test cell structure does not comprise any additional contact pads or contact lines for contacting to an external device, this test cell structure may advantageously be employed in combination with a corresponding test cell receiving structure, thereby enabling the design of a test cell geometry that is identical to present or future design rules except for any variation in the distances between the central bond bumps and their associated peripheral bond bumps.

According to still another aspect of the present invention, a method of determining an electrical property of adjacent bond bumps in a test cell structure is provided, wherein the method comprises providing a substrate, forming an insulation layer on the substrate, and forming a plurality of bond bumps with varying distances therebetween to establish a test structure. The method further comprises electrically connecting the bond bumps to a measurement device and determining an electrical property of the bond bumps with respect to the distance of two of the bond bumps.

In a further variation of the method of the present invention, the test cell structure is confined in an environment in which environmental conditions can be adjusted. In this manner, influences such as increased or decreased temperatures causing thermal stress and/or enhanced radiation and/or over-pressure and under-pressure and/or a varying humidity may be investigated with respect to a decreasing pitch between adjacent bond bumps.

In a further variation of the method, a test cell receiving structure is provided that corresponds to the test cell structure, such that electrical characteristics of adjacent bond bumps in a flip chip bonded structure with respect to decreasing distance between the bumps can be obtained.

### BRIEF DESCRIPTION OF THE DRAWINGS

The invention may be understood by reference to the following description taken in conjunction with the accompanying drawings, in which like reference numerals identify like elements, and in which:

FIG. 1 is a schematic top view of a test cell structure in accordance with one embodiment of the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Although the various regions and structures of a semiconductor device are depicted in the drawings as having very precise, sharp configurations and profiles, those skilled in the art recognize that, in reality, these regions and structures are not as precise as indicated in the drawings. Additionally, the relative sizes of the various features and doped regions depicted in the drawings may be exaggerated or reduced as compared to the size of those features or regions on fabricated devices. Nevertheless, the attached drawings are included to describe and explain illustrative examples of the present invention.

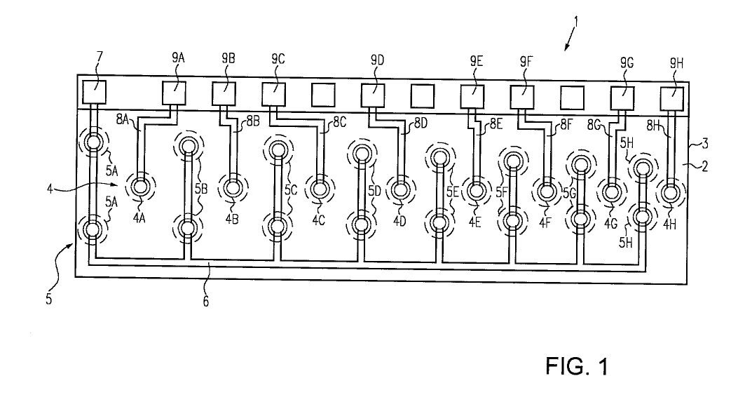

FIG. 1 shows a schematic top view of a test cell structure in conformity with one embodiment of the present invention. In FIG. 1, a test cell structure 1 comprises a substrate 3 having an at least partially insulating surface that is not shown in FIG. 1. On the substrate 3, an insulation layer 2 is formed. In and/or on the insulation layer 2, a plurality of central bond bumps 4 (4a . . . 4h) and a plurality of peripheral bond bumps 5 are formed. The plurality of peripheral bond bumps 5 are grouped into pairs 5a . . . 5h, wherein each member of a pair of peripheral bond bumps has substantially the same distance to the corresponding central bond bump. For example, the two peripheral bond bumps of pair 5a are substantially equally spaced apart from central bond bump 4a, and so on. The peripheral bond bumps 5a . . . 5h are electrically connected to each other and to a peripheral contact pad 7 by a peripheral contact line 6. Each of the central bond bumps 4a . . . 4h is connected to a respective central contact pad 9a . . . 9h by a corresponding central contact line 8a . . . 8h.

The test cell structure depicted in FIG. 1 may be produced in conformity with the following process flow. First, the substrate 3 is provided and prepared to have a surface that is at least partially insulating, i.e., that has a number of areas that are electrically isolated from each other so as to allow the formation of contact portions thereon which are electrically isolated from each other. The substrate 2 can be any appropriate substrate, but as previously mentioned, preferably a substrate is selected that exhibits similar thermal and mechanical properties as found in semiconductor chips. For example, a silicon substrate, a glass substrate, or any other suitable semiconductor material may be selected as the substrate 2. Moreover, the substrate 2 may comprise several layers of material formed thereon, so as to resemble thermal and mechanical characteristics of an actual semiconductor chip. Thereafter, contact portions and the peripheral contact line 6 and the central contact lines 8a . . . 8h are formed by photolithography and etching as is well known in the art of semiconductor manufacturing. Next, insulation layer 2 is deposited and patterned to have openings in which the central and peripheral bond bumps are to be formed. The insulation layer 2 may comprise one or more sub-layers of different materials, for example, silicon nitride or silicon dioxide, or may comprise any other appropriate material, preferably a material that is used in present semiconductor chips or will be used in a future chip generation. Finally, the central and peripheral bond bumps are formed in and on the openings in the insulation layer 2. Any appropriate material, including gold, platinum, lead, tin, titanium, and the like, may be used alone or in any combination as required.

The test cell structure 1 may be connected to an external measurement device (not shown), such as a voltage source, a constant current source, and the like, via the central contact pads 9a . . . 9h and the peripheral contact pad 7. Thus, test cell structure 1 allows the precise determination of an electrical property, such as the resistance between adjacent bond bumps, like bond bump 4a and the peripheral bond bumps 5a associated therewith, and the electrical resistance between the central bond bump 4b and the adjacent peripheral bond bumps 5b. In order to relate the electrical resistance measured between these bond bumps to the respective distance of the peripheral bond bumps to the respective central bond bumps with a minimum of measurement actions, a distance between bond bump 4a and bond bumps 5b is significantly larger than the distance between the bumps 5a and 4a. This insures that the electrical resistance primarily depends on the distance between, for example, central bond bump 4a and peripheral bond bumps 5a rather than on the distance between central bond bump 4a and the peripheral bond bumps 5b, since any leakage current or short will most likely occur between closely spaced bumps rather than between farther spaced bumps.

The distance between bumps 5a and 4a is referred to as a first distance. Preferably, the first distance is selected to fall in a range that is typical for the distance of bond bumps in integrated circuits. For example, the first distance is selected to be 80 μm or less. Similarly, the distance between bumps 5b and bump 4b is referred to as a second distance, wherein the second distance is less than the first distance. By selecting the central contact pad 9a, a resistance measurement between peripheral contact pad 7 and central contact pad 9a is a resistance value that mainly depends on the first distance. Similarly, by selecting the central contact pad 9b, the resulting resistance value is substantially dominated by the second distance, since the peripheral bond bumps 5c are separated from the central bond bump 4b by a distance that is larger than the second distance, as previously explained. In the same manner, the remaining peripheral bond bumps 5c . . . 5h are related to the corresponding central bond bumps 4c . . . 4h, and selection of the corresponding central contact pads 9c . . . 9h will yield resistance values that are substantially determined by the corresponding distances between associated peripheral and central bond bumps.

In this example, resistance values for eight different distances may be obtained either sequentially or in a parallel manner. As the skilled person will readily appreciate, the number of central bond bumps and associated peripheral bond bumps can be varied in numerous ways. Furthermore, the array of bond bumps may be arranged so that a central bond bump is associated with an arbitrary number of substantially equally spaced peripheral bond bumps. For example, each central bond bump may be associated with only one peripheral bond bump, or each central bond bump may be surrounded by four equally separated peripheral bond bumps to form a basic cell, wherein the distance of the peripheral bond bumps to the central bond bump gradually decreases in subsequent cells. In this way, it is guaranteed that the measurement results are substantially determined by respective distances between central bond bumps and peripheral bond bumps, thereby substantially eliminating any “geometrical influence” on the electrical resistance that might be caused by a directional dependency of the manufacturing process of the test cell structure. It should be noted that a basic cell is preferred in which a central bond bump is surrounded by four peripheral bond bumps, since this arrangement represents a typical configuration of a flip chip design in a semiconductor device. Although the electrical resistance between adjacent bond bumps is an important factor with regard to quality and reliability, particularly when the resistance becomes very low, other electrical properties, such as capacitance and inductance between adjacent bond bumps, may be determined with the test cell structure according to the present invention.

Since environmental conditions, such as high energy radiation in the form of X-rays, charge particles, cosmic particles, etc., pressure, humidity and temperature, as well as internal heat created during the operation of a semiconductor device, significantly affect quality and performance of a semiconductor device, and particularly affect the bonding area of a semiconductor device, it is also important to study the relation between the pitch of adjacent bond bumps and environmental and operational parameters as mentioned above. The present invention may be used to obtain the required information by using an appropriate test cell structure.

For example, a high temperature gradient may lead to thermal stress in a semiconductor device that may cause a variation of the pitch of the bond bumps. Consequently, a pitch that is assessed to be appropriate at a low temperature gradient may prove cumbersome when excessive heat is produced in the semiconductor device. Furthermore, in general the bond bumps are relatively thick (a few tenths of μm) and a high density of densely arranged bond bumps may significantly reduce the amount of high energetic particles, for example, cosmic rays, entering the semiconductor device. On the other hand, materials used for forming the bond bumps may comprise inherent radiation sources, for example, lead emits a certain amount of alpha particles that may adversely affect the performance of the device, so that it may be desirable to find an optimum bump density, and therefore an optimum pitch, that, on the one hand, minimizes inherently created radiation, but, on the other hand, provides a maximum immunity against external high-energetic radiation. Furthermore, storage and/or operation of semiconductor devices in ambience of reduced or increased pressure may cause mechanical stress in the device and result in a variation of the pitch of bond bumps. To be able to manufacture reliable semiconductor devices for use in, e.g., avionics and astrionics, requires a manufacturing process flow that takes into consideration the above parameters. Accordingly, the test cell structure of the present invention provides an efficient means for effectively studying the influence of these parameters on the electrical characteristics of the bond bumps.

Moreover, the present invention provides a test cell receiving structure comprised of a wiring substrate and respective central and peripheral bond pads that preferably correspond to the respective central and peripheral bond bumps of a test cell structure as is exemplified in FIG. 1. The wiring substrate may be a conventional insulating resin substrate or a polyamide substrate, as it is well known in the art. Furthermore, the wiring substrate may comprise wiring lines that connect the central bond pads with respective central contact terminals and connect the peripheral bond pads with one or more peripheral contact terminals. Preferably, a test cell structure matching the design of the test cell receiving structure is flip chip bonded to the wiring substrate and the bond bumps of the test cell structure are reflowed so as to provide electrical and physical contact to the wiring substrate.

Regarding the design of the test cell receiving structure, the materials, and the process flow for forming the same, similar criteria as given above with reference to the test cell structure apply in this case as well. That is, the test cell receiving structure is preferably constructed in conformity with design rules of a corresponding semiconductor device, so that an analysis of electrical characteristics of flip chip bonded devices may be obtained that is closely related to present or future semiconductor devices. Moreover, the test cell receiving structure alone or in combination with a test cell structure bonded thereto may be subjected to varying environmental conditions and/or varying operating conditions so as to assess quality and reliability of bonded connections with respect to the decreased pitch of adjacent bond bumps.

In a further embodiment, a test cell structure may be provided without any peripheral and central contact pads and without any peripheral and central contact lines, so that the test cell structure may be designed exactly in conformity with corresponding design rules of a semiconductor device, except for the varying distance between center and peripheral bond bumps. An illustrative embodiment is, for example, the test cell structure depicted in FIG. 1, but without the central contact pads 9a, . . . , 9h, without the central contact lines 8a, . . . , 8h, without the peripheral contact pad 7, and without the peripheral contact line 6. Regarding the configuration of the test cell structure according to this embodiment, the same criteria as given above with reference to FIG. 1 apply here as well. Due to the omitted contact pads, this test cell structure is preferably used in combination with a matching test cell receiving structure which then enables electrical connection of the test cell structure via corresponding contact terminals provided at the test cell receiving structure. Accordingly, decreasing the pitch of adjacent bond bumps in a semiconductor device can be effectively simulated while the remaining device features may precisely resemble the design rules for the corresponding semiconductor device. Moreover, environmental conditions and operating parameters may be varied so as to estimate the characteristics of the bonding structure with respect to decreasing feature sizes under different conditions.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A test cell structure for determining electrical characteristics between adjacent bond bumps, comprising:
a substrate having an at least partially insulating surface;
a first central bond bump formed on the at least partially insulating surface;
a second central bond bump formed on the at least partially insulating surface;
a first peripheral bond bump formed on the insulating surface and spaced apart from the first central bond bump by a first distance;
a second peripheral bond bump formed on the insulating surface and spaced apart from the second central bond bump by a second distance, the second distance being less than the first distance;
an insulation layer at least partially formed between the first and second central bond bump and the first and second peripheral bond bumps;
a first central contact pad for providing electrical contact to an external device, connected to the first central bond bump by a first central contact line;
a second central contact pad for providing electrical contact to an external device, connected to the second central bond bump by a second central contact line; and
a peripheral contact pad for providing electrical contact to an external device, connected to the first and second peripheral bond bumps by a peripheral contact line,
wherein an electrical property of the first and second central bond bumps and the first and second peripheral bond bumps with respect to the first and second distances are measurable via the first and second central contact pads and the peripheral contact pad.

2. The test cell structure of claim 1, comprising a plurality of first peripheral bond bumps and a plurality of second peripheral bond bumps, each of the plurality of first and second peripheral bond bumps being separated from the first and second central bond bumps by substantially the first distance and the second distance, respectively.

3. The test cell structure of claim 2, further comprising a plurality of third central bond bumps and a respective number of third central contact pads connected to the third central bond bumps via a respective number of third central contact lines, each of the third central bond bumps having a plurality of adjacent third peripheral bond bumps substantially equally separated therefrom by a respective third distance, each of the third peripheral bond bumps being connected to the peripheral contact pad.

4. The test cell structure of claim 3, wherein the first, second, and third central bond bumps are arranged in a symmetric manner.

5. The test cell structure of claim 4, wherein the first, second, and third central bond bumps are arranged in a substantially straight line.

6. The test cell structure of claim 3, wherein all of the third distances are different.

7. The test cell structure of claim 3, wherein all of the third distances are less than the second distance.

8. The test cell structure of claim 3, wherein each central bond bump has two 5 adjacent peripheral bond bumps.

9. The test cell structure of claim 1, wherein the first distance is 80 μm or less.

10. A test cell receiving structure for receiving a test cell structure by flip chip bonding, comprising:
a wiring substrate;
a first central bond pad, formed on the wiring substrate, for bonding thereon a bond bump;
a second central bond pad, formed on the wiring substrate, for bonding thereon a bond bump;
a first peripheral bond pad for bonding thereon a bond bump, formed on the wiring substrate, and spaced apart from the first central bond pad by a first distance; and
a second peripheral bond pad for bonding thereon a bond bump, formed on the wiring substrate, and spaced apart from the second central bond pad by a second distance, the second distance being less than the first distance.

11. The test cell receiving structure of claim 10, comprising a plurality of first peripheral bond pads and a plurality of second peripheral bond pads, each of the plurality of first and second peripheral bond pads being separated from the first and second central bond pads by substantially the first distance and the second distance, respectively.

12. The test cell receiving structure of claim 11, further comprising a plurality of third central bond pads, each of the third central bond pads having a plurality of adjacent third peripheral bond pads substantially equally separated therefrom by a respective third distance.

13. The test cell receiving structure of claim 12, wherein the first, second, and third central bond pads are arranged in a symmetric manner.

14. The test cell receiving structure of claim 13, wherein the first, second, and third central bond pads are arranged in a substantially straight line.

15. The test cell receiving structure of claim 11, wherein all of the third distances are different.

16. The test cell structure of claim 15, wherein all of the third distances are less than the second distance.

17. The test cell receiving structure of claim 11, wherein each of the central bond pads has two adjacent peripheral bond pads.

18. The test cell receiving structure of claim 11, wherein the wiring substrate comprises a wiring arrangement and a plurality of solder balls such that each of the central bond pads and each of the peripheral bond pads is connected to an individual one of the plurality of solder balls.

19. The test cell receiving structure of claim 11, wherein the wiring substrate comprises a wiring arrangement and a plurality of solder balls such that each of the central bond pads is connected to an individual one of the plurality of solder balls to at least one further solder ball.

20. The test cell receiving structure of claim 11, wherein the first distance is 80 μm or less.

21. A test cell structure for determining electrical characteristics between adjacent bond bumps, comprising:
a substrate having an at least partially insulating surface; and
a plurality of central bond bumps formed on the insulating surface; each central bond bump having two or more adjacent peripheral bond bumps spaced apart therefrom by a substantially equal distance, wherein at least two of the central bond bumps have distances to their corresponding peripheral bond bumps that are different from each other.

22. A method of determining an electrical property of adjacent bond bumps in a test cell structure, comprising:
providing a substrate;
forming an insulation layer on the substrate; forming a plurality of bond bumps with varying distances therebetween to establish a test structure;
electrically connecting the bond bumps to a measurement device; and
determining an electrical property of the bond bumps with respect to the distance of respective two of the bond bumps.

23. The method of claim 22, wherein determining an electrical property includes determination of at least one of electrical resistance, capacitance, and inductance.

24. The method of claim 23, further comprising confining the test cell structure in an environment of adjustable environmental conditions.

25. The method of claim 24, wherein the environmental conditions include at least one of temperature, pressure, humidity and radiation.

26. The method of claim 22, further comprising providing a test cell receiving structure having bond pads that correspond to the bond bumps of the test cell structure, and flip chip bonding the test cell structure to the test cell receiving structure so as to determine an electrical property of adjacent bond bumps when combined to the test cell receiving structure by flip chip bonding.

27. The method of claim 26, wherein electrical connection to the measurement device is established via contact portions provided on the test cell receiving structure.

28. The method of claim 26, wherein electrical connection to the measurement device is established via contact pads provided on the test cell structure.
